(19) United States
(12) Patent Application Publication
(10) Pub. No.: US 2004/0248016 A1
(43) Pub. Date: Dec. 9, 2004

(54) Method of designing a reticle and forming a semiconductor device therewith

(76) Inventors: Kevin D. Lucas, Austin, TX (US); Robert E. Boone, Austin, TX (US); Russell L. Carter, Taylor, TX (US); Willard E. Conley, Austin, TX (US)

Correspondence Address: FREESCALE SEMICONDUCTOR, INC., LAW DEPARTMENT, 7700 WEST PARMER LANE MD:TX32/PL02, AUSTIN, TX, 78729, US

(21) Appl. No.: 10/455,856

(22) Filed: Jun. 6, 2003

(51) Int. Cl. G03F 9/00; G03C 5/00

(52) U.S. Cl. 430/5; 430/394; 430/311; 430/312; 430/313

(57) ABSTRACT

A method of designing and forming a reticle (404), as well as the manufacture of a semiconductor substrate (410) using the reticle, includes defining a first edge of a reticle layout file. The first edge corresponds to a reference feature (12,14). The method further includes using the reference feature to insert a subresolution assist feature (62,64) into the reticle layout file. The subresolution assist feature is at an angle (θ) with respect to a line (82,84) containing the first edge, wherein the angle differs from 90 degrees. In one embodiment, the subresolution assist features can be manually or automatically inserted into the layout file after the locations of the assist features have been determined. The subresolution assist features are not patterned on the substrate, but assist in forming resist features of uniform dimension.

### FIELD OF THE INVENTION

The invention relates generally to the field of semiconductors and photolithography, and more specifically to a method of designing a reticle and forming a semiconductor device therewith.

### RELATED ART

As part of semiconductor device manufacturing, a photolithographic process is used to form a pattern in a photoresist layer on a semiconductor wafer. The photolithographic process includes transferring light through a reticle and lenses onto the photoresist layer. As used herein, the terms mask, photomask, and reticle may be used interchangeably. The pattern in the photoresist layer is subsequently transferred to an underlying layer (e.g., copper) on the semiconductor wafer to form a semiconductor device feature (e.g., a via). However, the photolithography is subject to processing variations such as focus variations. In addition, semiconductor devices are requiring smaller and smaller dimensions in forming future generations of products.

The patterns on the reticle are often not transferred without error to the photoresist layer as a result of the processing variations. In other words, the patterns on the reticle are transferred with error. Often the processing variations result in smaller features than designed being printed. Focus variations are more severe for isolated features (i.e., features without other features in close proximity) than for dense features (i.e., features with other features in close proximity). Therefore, a need exists for a photolithographic process that allows for improved photolithographic patterning of isolated features and increased processing control of forming isolated features in a semiconductor manufacturing process.

Subresolution assist features have been used in an effort to improve wafer patterning processing margin. Such subresolution assist features are placed opposite to an edge of an isolated design feature. However, such placement causes difficulties in design locations where a first design feature meets with another design feature. The placement leads to small spaces between assist features which are difficult to inspect on the reticle and difficult to implement in software.

Accordingly, there exists a need for improved reticle inspection, improved wafer patterning processing margin, and ease of subresolution assist feature algorithm implementation.

### SUMMARY

According to one embodiment, a method of designing and forming a reticle, as well as the manufacture of a semiconductor substrate using the reticle, includes defining a first edge of a reticle layout file. The first edge corresponds to a reference feature. The method further includes using the reference feature to insert a subresolution assist feature into the reticle layout file. The subresolution assist feature is at an angle (θ) with respect to a line containing the first edge, wherein the angle differs from 90 degrees.

### BRIEF DESCRIPTION OF THE DRAWINGS

The embodiments of the present disclosure are illustrated by way of example and not limited by the accompanying figures, in which like references indicate similar elements, and in which:

FIG. 1 is an illustrative view of a target design having subresolution assist features;

FIG. 2 is an illustrative view of a depth of focus range of the target design of FIG. 1;

FIG. 3 is an illustrative view of another target design having subresolution assist features;

FIG. 4 is an illustrative view of yet another target design having subresolution assist features;

FIG. 5 is an illustrative view of a target design having an improved subresolution assist feature according to one embodiment of the present disclosure;

FIG. 6 is an illustrative view of a depth of focus range of the target design of FIG. 5;

FIG. 7 is an illustrative view of the target design of FIG. 5 having an improved subresolution assist feature formed according to one embodiment of the present disclosure;

FIG. 8 is an illustrative view of the target design of FIG. 5 having an improved subresolution assist feature formed according to another embodiment of the present disclosure;

FIG. 9 is an illustrative view of the target design of FIG. 3 having an improved subresolution assist feature formed according to one embodiment of the present disclosure;

FIG. 10 is an illustrative view of the target design of FIG. 4 having an improved subresolution assist feature formed according to another embodiment of the present disclosure;

FIG. 11 is an illustrative view showing a depth of focus of a target design having an improved subresolution assist feature according to one embodiment of the present disclosure;

FIG. 12 is an illustrative view of a target design having an improved subresolution assist feature according to another embodiment of the present disclosure;

FIG. 13 is a flow diagram view of a method for designing a reticle with improved subresolution assist features according to one embodiment of the present disclosure; and

FIG. 14 is a block diagram view of a system for forming a semiconductor device using a reticle having improved subresolution assist features according to one embodiment of the present disclosure.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present disclosure.

### DETAILED DESCRIPTION

According to an embodiment of the present disclosure, subresolution assist features are provided to a reticle and not placed opposite to edges of a design feature. In one embodiment, the subresolution assist features are connected to a main feature or are placed at an angle to design feature edges, as further discussed herein. The embodiments allow for improved coverage of the assist features with improved process margin and reduced reticle inspection issues.

As used herein, resolution limit refers to a resolution limit of the lithography tool used to expose a resist layer. Subresolution is below that resolution limit. Assist features are “subresolution” reticle features because the corresponding image, when projected onto the resist layer, is below the resolution limit and does not substantially pattern the underlying resist layer. For example, a lithography tool may have a 4× projection system: and a resolution limit of 0.2 microns. An assist feature with a width of 0.60 microns on the reticle is a subresolution reticle feature because the projected image would be 0.15 microns and is below the resolution limit of 0.2 microns.

The embodiments discussed herein can be used for a wide variety of wavelengths of radiation sources, numerical aperture of lenses, and resist materials used in forming semiconductor devices. Examples of wavelengths used can range from approximately 436 nanometers (g-line) and lower. Other commonly used wavelengths include approximately 365 nanometers (i-line), approximately 248, 193, or 157 nanometers (deep ultraviolet or DUV), and approximately 13 nanometers (extreme ultraviolet or EUV). The numerical aperture of the lenses are generally in a range of approximately 0.45 to 0.90. The resist materials typically are determined by the radiation source used, as the materials within the resist must be activated optimally at the wavelength of the radiation source used. Other resist materials, light source configurations, numerical apertures, and wavelengths can be used. The present embodiments could also be used for longer wavelength systems to extend a useful life thereof before having to replace the equipment.

The present embodiments can be used during the design and formation of a reticle. During design, a semiconductor device layout file is generated. Portions of the layout file corresponding to subresolution assist features are made. The subresolution assist features can be manually or automatically inserted into the layout file after the locations of the assist features have been determined.

After the layout file is completed, the layout file can be transferred to a reticle fabrication tool, such as an electron beam writer. Typically, the layout file is downloaded into a computer coupled to the reticle fabrication tool. A reticle substrate is processed to form a reticle having a desired pattern of a *target design. The reticle can be then be used to form a semiconductor device by exposing and developing a resist layer to give it a resist profile with features according to the pattern of the reticle.

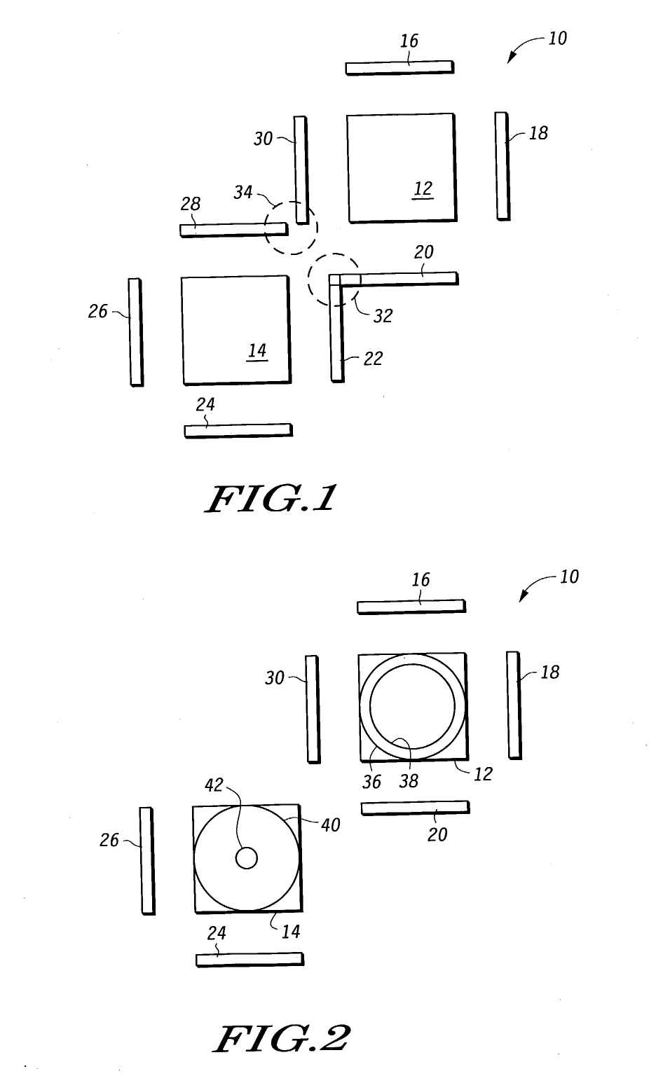

FIG. 1 is an illustrative view of a target design 10 including target device features 12 and 14. Target device features 12 and 14 may comprise, for example, vias. The target design 10 further includes subresolution assist features, as identified by reference numerals 16-30, placed parallel to the edges of respective target device features 12 and 14. Assist features 20 and 22 overlap at a traditional 90 degree angle at respective end portions thereof, as indicated by reference numeral 32. The traditional angle can also include zero degrees. At location 32, there exists a risk of the overlapping assist features 20 and 22 resolving in the photoresist pattern of a wafer or substrate. In addition, assist features 28 and 30 are in close proximity, without overlapping, at respective end portions thereof, as indicated by reference numeral 34. At location 34, there exists a risk of diminished reticle manufacturing capability or reticle inspection capability of assist features 28 and 30. With typical reticle layout processing, one or more of the assist features 20, 22, 28, and/or 30 would be removed from the reticle layout to overcome the deficits mentioned above.

FIG. 2 is an illustrative view of a depth of focus range of the target design 10 of FIG. 1. Target design 10 includes target device features 12 and 14, as well as, subresolution assist features 16, 18, 20, 24, 26 and 30 placed parallel to the edges of respective target device features 12 and 14. Note that in FIG. 2, assist features 22 and 28 have been removed as indicated above. At best processing conditions, a best focus image of a resultant wafer pattern is indicated by reference numerals 36 and 40 for respective target device features 12 and 14. At degraded processing conditions, a defocused image of a resultant wafer pattern is indicated by reference numerals 38 and 42 for respective target device features 12 and 14. Note that at best focus conditions, wafer patterns 36 and 40 are substantially similar in size. However, at defocused conditions, wafer pattern 38 is substantially larger than wafer pattern 42. Such a large variation in the size of wafer pattern 42 between best focus conditions and defocused conditions is undesirable and may lead to undesired process and/or circuit failure.

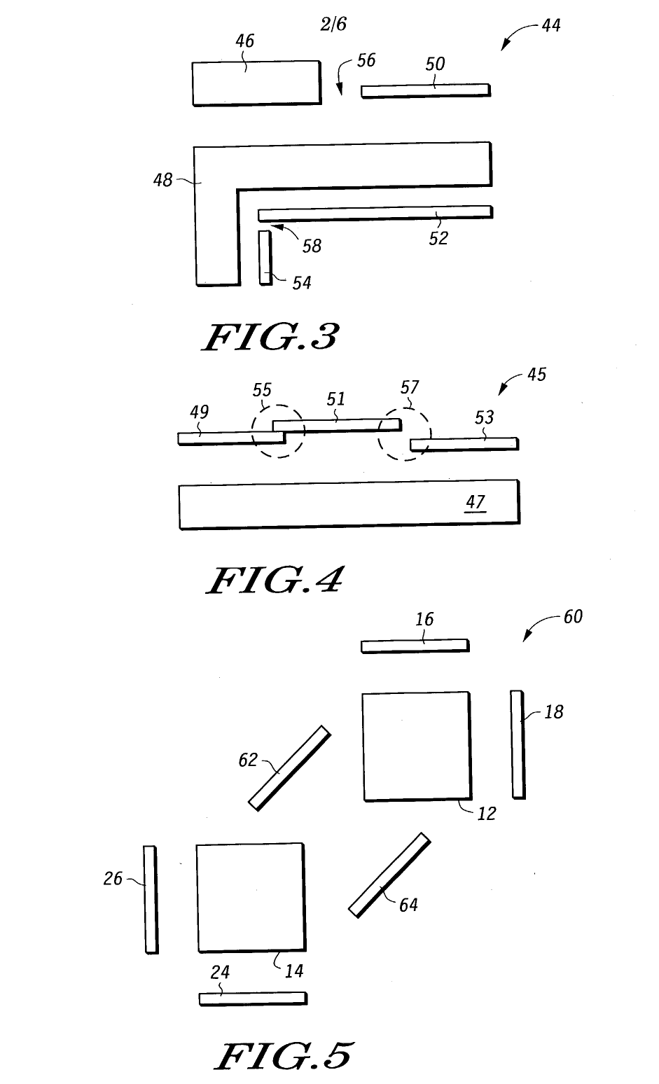

FIG. 3 is an illustrative view of another target design 44 including target device features 46 and 48. Target design 44 further includes subresolution assist features 50, 52 and 54, placed parallel to the edges of respective target device features 46 and 48. Assist feature 50 is in close proximity at a respective end portion of target device feature 46 as indicated by reference numeral 56. Assist features 52 and 54 are in close proximity, without overlapping at respective end portions thereof, as indicated by reference numeral 58. At locations 56 and 58, there exists a risk of diminished reticle manufacturing capability or reticle inspection capability of the associated assist features.

FIG. 4 is an illustrative view of a target design 45 including target device feature 47, for example, a polysilicon line or gate electrode. The target design 45 further includes subresolution assist features 49, 51 and 53 placed parallel to the edge of respective target device feature 47. Target design 45 may include other target device features not shown. Assist features 49 and 51 contact one another at respective end portions thereof, as indicated by reference numeral 55. At location 55, there exists a risk of overlap of assist features 49 and 51 resolving in the photoresist pattern of a wafer or substrate. In addition, assist features 51 and 53 are in close proximity, without overlapping, at respective end portions thereof, as indicated by reference numeral 57. At location 57, there exists a risk of diminished reticle manufacturing capability or reticle inspection capability of assist features 51 and 53.

FIG. 5 is an illustrative view of a target design 60 having an improved subresolution assist feature according to one embodiment of the present i disclosure. Target design 60 includes target device features 12 and 14, for example, vias. The target design 60 further includes subresolution assist features 16, 18, 24 and 26 placed parallel to the edges of respective target device features 12 and 14. In addition, target design 60 includes assist features 62 and 64 placed at an angle with respect to edges of the two target device features 12 and 14, as shown in FIG. 5 and as will be further discussed herein. Note that the embodiment of FIG. 5 is void of assist features that overlap or are in close proximity to each other. Accordingly, the target design 60 provides for a reticle having improved reticle manufacturing capability and/or reticle inspection capability.

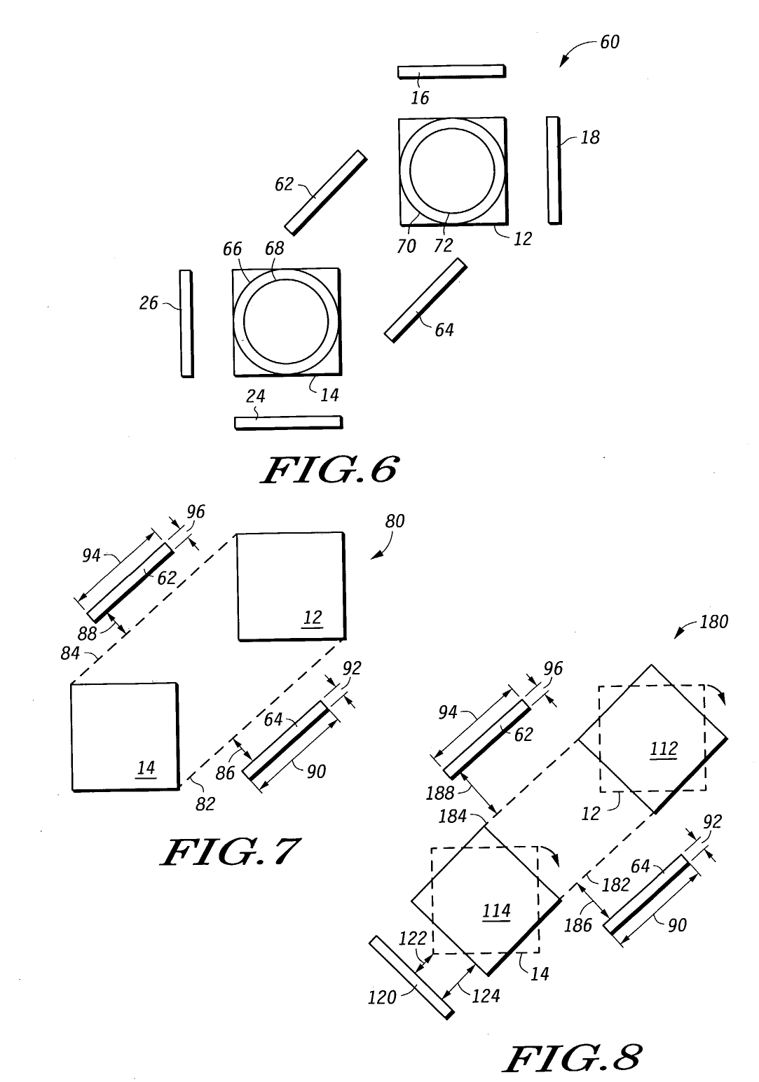

FIG. 6 is an illustrative view of a depth of focus range of the target design 60 of FIG. 5. With the angled subresolution assist features 62 and 64 and at best processing conditions, a best focus image of a resultant wafer pattern is indicated by reference numerals 66 and 70 for respective target device features 12 and 14. At degraded processing conditions, a defocused image of a resultant wafer pattern is indicated by reference numerals 68 and 72 for respective target device features 12 and 14. At best focus conditions, wafer patterns 66 and 70 are substantially similar in size to respective target device features 12 and 14. In addition, at defocused conditions, wafer patterns 68 and 72 are also substantially similar in size to the respective target device features 12 and 14, only slightly smaller. As a result, a minimum in variation in the size of wafer patterns (66,70) or (68,72) can be obtained, leading to a desired process and/or circuit performance.

A benefit of the present embodiments is that the subresolution assist features help in achieving a more consistent width of the developed resist features across a substrate surface, whether the feature is found in a dense feature pattern, semi-dense feature pattern, or isolated feature pattern. The consistency in the width should still be maintained, even with small variations in the lithographic processing conditions.

FIG. 7 is an illustrative view of target design 80 having an improved subresolution assist feature formed according to one embodiment of the present disclosure. Target design 80 includes target device features 12 and 14. Target design 80 also includes assist features 62 and 64 placed at an angle with respect to edges of the two target device features 12 and 14. In the method of forming assist features 62 and 64, geometric operations are performed upon edges of target devices 12 and 14 to create derived edges 82 and 84 which are disposed at an angle, greater than 0 degrees and less than 90 degrees, from a respective first edge of target devices 12 and 14. With respect to the derived edges 82 and 84, assist features 64 and 62 are disposed parallel to the same. Assist feature 62 has a length 94, width 96, and is placed a distance 88 from the derived edge 84. Assist feature 64 has a length 90, width 92, and is placed a distance 86 from the derived edge 82. The particular lengths, widths, and distances of assist features 62 and 64 can be determined according to the particular design requirements of a given application.

FIG. 8 is an illustrative view of target design 180 having an improved subresolution assist feature formed according to one embodiment of the present disclosure. Target design 180 includes target device features 12 and 14. Target design 80 also includes assist features 62 and 64 placed at an angle with respect to edges of the two target device features 12 and 14. In the method of forming assist features 62 and 64, geometric operations are performed upon edges of target devices 12 and 14 to create derived features 112 and 114. For example, each of the target devices is rotated about its center to create the respective derived features. Derived features 112 and 114 are disposed at an angle, greater than 0 degrees and less than 90 degrees, from a respective first edge of target devices 12 and 14.

Geometric operations are performed upon edges of derived features 112 and 114 to create derived edges 182 and 184. Further geometric operations are then performed upon the derived edges 182 and 184 to create assist features 62 and 64. With respect to the derived edges 182 and 184, assist features 64 and 62 are disposed parallel to the same. Assist feature 62 has a length 94, width 96, and is placed a distance 188 from the derived edge 184. Assist feature 64 has a length 90, width 92, and is placed a distance 186 from the derived edge 182. The particular lengths, widths, and distances of assist features 62 and 64 can be determined according to the particular design requirements of a given application.

FIG. 9 is an illustrative view of the target design of FIG. 3 having an improved subresolution assist feature formed according to one embodiment of the present disclosure. FIG. 9 is an illustrative view of target design 144 including target device features 46 and 48. Target design 144 further includes subresolution assist features 150, 152, 154 and 156. Subresolution assist features 150, 152 and 156 are placed parallel to the edges of respective target device features 46 and 48. Assist feature 150 is also attached at a respective end portion of target device feature 46 as indicated by reference numeral 162.

Subresolution assist feature 154 is placed at an angle θ, greater than 0 degrees and less than 90 degrees, to the respective edges of target device feature 48, as indicated by reference numeral 160. In addition, subresolution assist! feature 154 overlaps respective end portions of subresolution assist features 152 and 156. The edges of subresolution assist feature 154 are disposed relative to the respective edges of subresolution assist features 152 and 156 at an angle, greater than 0 degrees and less than 90 degrees. Note that the embodiment of FIG. 9 is void of assist features that are merely in close proximity to each other.

Accordingly, the target design 144 provides for a reticle having improved reticle manufacturing capability and/or reticle inspection capability. Inn addition, the embodiment of FIG. 9 is void of assist features edges that overlap or merge with another assist feature at an angle equal to 90 degrees. Accordingly, the target design 144 provides for lower risk of overlapping assist features 152, 154, 156 resolving in the photoresist pattern in a wafer or substrate during a lithographic patterning process.

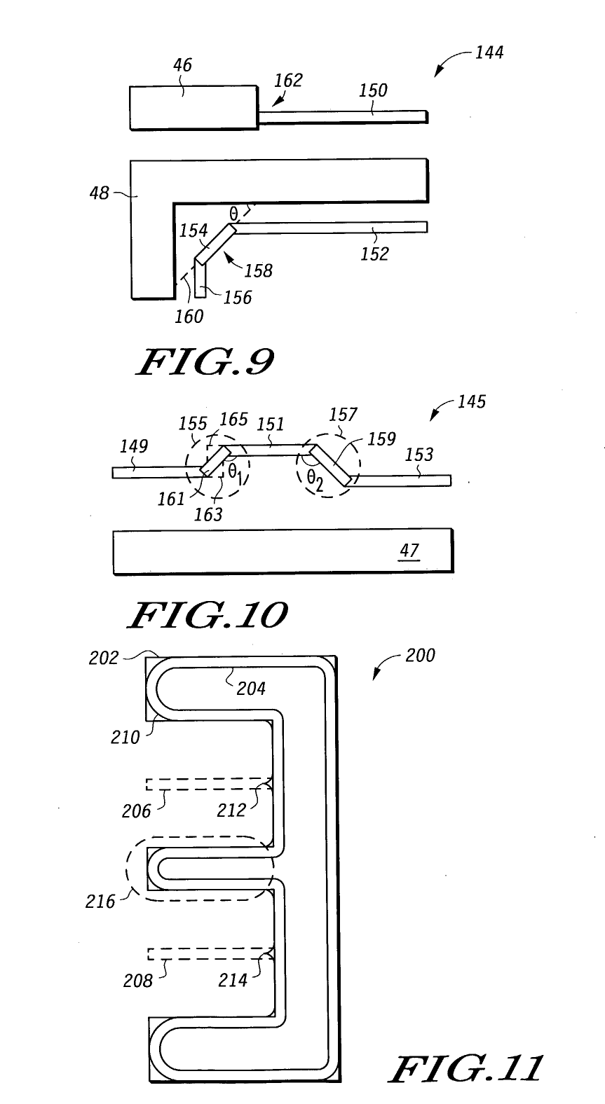

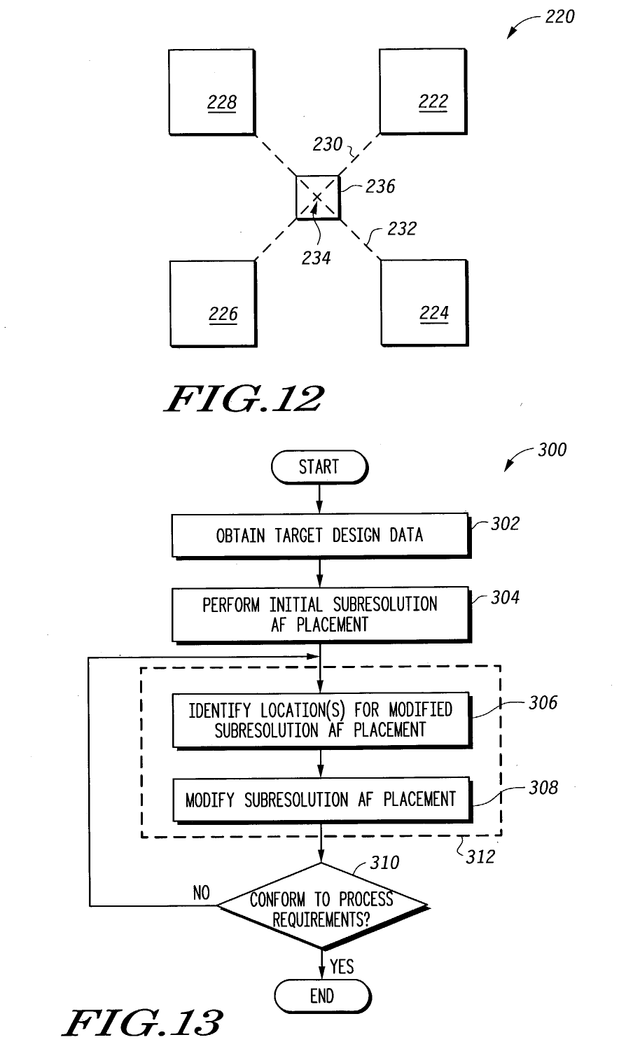

FIG. 10 is an illustrative view of the target design of FIG. 4 having an improved subresolution assist feature formed according to another embodiment of the present disclosure. More particularly, FIG. 10 is an illustrative view of a target design 145 including target device feature 47, for example, a polysilicon line or gate electrode. The target design 145 further includes subresolution assist features 149, 151 and 153 placed parallel to a respective edge of target device feature 47. In addition, target design 145 further includes subresolution assist features 159, and 161 placed at an angle other than 90 degrees, to a respective edge of target device feature 47. Target design 145 may also include other target device features not shown.

As shown, angled subresolution assist feature 159 overlaps assist features 151 and 153 at respective end portions thereof, as indicated by reference numeral 157. More particularly, end portions of subresolution assist feature 159 overlap end portions of assist features 151 and 153, wherein further the subresolution assist feature 159 is disposed at an angle different from 90 degrees with respect to assist features 151 and 153.

In a similar manner, angled subresolution assist feature 161 overlaps assist features 149 and 151 at respective end portions thereof, as indicated by reference numeral 155. That is, respective ends of assist feature 161 overlap a corresponding end region of assist features 149 and 151, wherein assist feature 161 is disposed at an angle other than 90 degrees. In comparison, with reference to FIG. 4, assist features 49 and 51 are in parallel to one another and also contact one another at respective end portions thereof as indicated by reference numeral 55. As indicated above, at location 55 there exists a risk of the end portion contact of assist features 49 and 51 resolving in the photoresist pattern of a wafer or substrate during a lithographic process. With reference again to FIG. 10, reference numerals 163 and 165 point to phantom portions of resist features 49 and 51 of FIG. 4 which have been modified according to one embodiment of the present disclosure. In other words, according to one embodiment of the present disclosure, the original resist features 49 and 51 of FIG. 4 were also modified, in addition to placement of the angled subresolution assist feature 161.

Accordingly, the embodiment of FIG. 10 is void of assist features that are merely in close proximity to each other. Furthermore, the target design 145 provides for a reticle having improved reticle manufacturing capability and/or reticle inspection capability. Note also that the embodiment of FIG. 10 is void of assist features edges that merge or overlap at an angle equal to 90 degrees. Accordingly, the target design 145 provides for lower risk of the overlapping assist features 149, 151, 153, 159, and 161 resolving in a photoresist pattern on a wafer or substrate during a lithographic process patterning step.

FIG. 11 is an illustrative view showing a depth of focus of a target design having an improved subresolution assist feature according to one embodiment of the present disclosure. In particular, FIG. 11 is an illustrative view of a target design 200 including target device feature 202. At degraded processing conditions and without subresolution assist features placed in target design 200, a defocused image of a resultant wafer pattern would occur as is indicated by reference numeral 204 for target device feature 202. Note that pattern 204 is substantially smaller in size than target device feature 202. Such variation in size between target device feature 202 and pattern 204 may lead to undesired process and/or circuit failure at a critical circuit location, such as indicated by reference numeral 216, for example an active transistor region. However, undesired process and/or circuit failure can be avoided with the addition of subresolution assist features according to one embodiment of the present disclosure.

With the use of subresolution assist features 206 and 208 placed in target design 200 and at degraded processing conditions, a defocused image of a resultant wafer pattern for target device feature 202 is possible, as indicated by reference numeral 210. Note that patterns 202 and 210 are substantially similar in size at the critical circuit location 216. In this embodiment, subresolution assist features 206 and 208 are placed parallel to edges of critical circuit location 216 in order to ensure the defocused image 202 at location 216 is substantially similar in size to the target device feature 202 at location 216. In addition, one end of each subresolution assist feature 206 and 208 is placed so as to touch (or slightly overlap) the target device feature 202 at a corresponding location as shown. As a result, the wafer pattern 210 exhibits small pattern bumps 212 and 214 at the locations where subresolution assist features 206 and 208 respectively touch the target device feature 202. As pattern bumps 212 and 214 are not at a critical circuit location, they do not cause undesired circuit performance. Accordingly, the embodiment of FIG. 11 is void of assist features that are merely in close proximity to each other or to a target device feature. Furthermore, the placement of subresolution assist features 206 and 208 in target design 200 leads to a desired process and/or circuit performance.

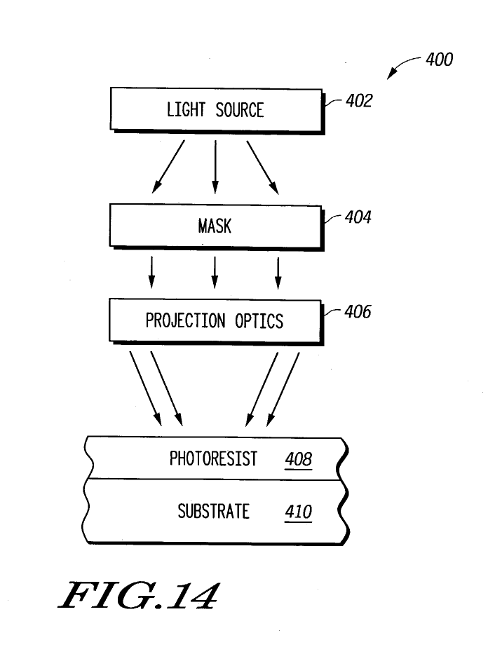

FIG. 12 is an illustrative view of a target design 220 having an improved subresolution assist feature according to yet another embodiment of the present disclosure. Target design 220 includes target device features 222, 224, 226 and 228. Target design 220 also includes subresolution assist feature 236 disposed between the target device features 222, 224, 226 and 228. In one method of forming subresolution assist feature 236, geometric operations are performed upon edges of target device features 222, 224, 226 and 228 to determine a placement and the forming of assist feature 236. For example, assist feature 236 can be formed between the inside edges of target devices 222, 224, 226 and 228, collectively.

In another method of forming assist feature 236, geometric operations may be performed upon corner edges of target devices 222, 224, 226>and 228 to create derived feature edges 230 and 232. Derived feature edges 230 and 232 intersect at the point indicated by reference numeral 234. Point 234 provides a center reference point for use in-forming subresolution assist feature 236 and is disposed between the inside edges of target devices 222, 224, 226 and 228, collectively. Geometric operations are then performed upon derived feature edges 230 and 232 to create subresolution assist feature 236. As shown, the edges of subresolution assist feature 236 are not directly opposite to any edge of target device features 222, 224, 226 and 228. In addition, the edges of assist feature 236 are disposed parallel to respective edges of target device features 222, 224, 226 and 228.

FIG. 13 is a flow diagram view of a method for designing a photomask with improved subresolution assist features according to one embodiment of the present disclosure. Method 300 starts with the obtaining of the target design data in step 302. An initial placement of subresolution assist features (AF) is then performed as indicated in step 304. In step 306, one or more locations are then identified for modified subresolution AF placement, the locations being determined suitable to place modified subresolution assist features. The method continues at step 308 with the placing of the modified subresolution assist features at the locations identified in step 306. In step 310, the method evaluates whether the results of step 308 conform to process requirements. If in step 310 the results do not conform to process requirements, then the method repeats steps 306 and 308, wherein the later steps are collectively indicated by reference numeral 312. If in step 310 the results do conform to process requirements, then the method is complete and is subsequently ended.

According to one embodiment, a method of designing a reticle for a semiconductor device includes defining a first edge of a reticle layout file, the first edge corresponding to a reference feature. The reference feature is used to insert a subresolution assist feature into the reticle layout file. The subresolution assist features can be manually or automatically inserted into the layout file after the location or locations of the assist features have been determined. The subresolution assist features are not patterned on the substrate, 15 but assist in forming resist features of uniform dimension.

The subresolution assist feature is principally disposed at an angle with respect to a line containing the first edge, the angle not being 90 degrees (i.e., is different from 90 degrees). In one embodiment, the reference feature includes one of a target device feature or a second subresolution assist feature. In addition, the method can include inspecting the reticle layout file to determine a location to be modified, prior to defining the first edge.

In another embodiment, using the reference feature to insert a subresolution assist feature into the reticle layout file includes rotating the reference feature from an initial layout position, defining a derived edge from the rotated reference feature, and using the derived edge to determine an insertion point and location for the angled subresolution assist feature. In one implementation, the method further includes inserting the subresolution assist feature substantially parallel to a line containing the derived edge.

The method further includes defining a second reference feature of the reticle layout file. In this embodiment, the second reference feature is rotated a prescribed amount, wherein a derived edge is defined from the rotated second reference feature. Furthermore, the reference feature can include one of a first target device feature or a second subresolution assist feature, while the second reference feature can include one of a second target device feature or a third subresolution assist feature.

In another embodiment, the first edge of the reference feature can comprise a first vertex of the reference feature. Accordingly, the step of using the reference feature to insert the subresolution assist feature includes using the first vertex to insert the subresolution assist feature. Furthermore, the step of using the reference also may include defining a derived edge extending from the first vertex and using the derived edge to insert the subresolution assist feature. In addition, the derived edge may extend from the first vertex of the reference feature to a second vertex of a second reference feature. In the later instance, the reference feature can comprise one of a first target device feature or a second subresolution assist feature, and the second reference feature can comprise one of a second target device feature or a third subresolution assist feature.

In yet another embodiment, the method further includes defining a second edge of a reticle layout file. The second edge corresponds to a second reference feature. In this embodiment, the step of using the reference feature to insert the subresolution assist feature includes using the reference feature and the second reference feature to insert the subresolution assist feature. The resulting subresolution assist feature is at a second angle with respect to a line containing the second edge, wherein the second angle differs from 90 degrees.

According to another embodiment, a method of designing a reticle for a semiconductor device includes defining a first feature of a reticle layout file, defining a second feature of the reticle layout file, and defining a third feature to connect the first feature to the second feature. The third feature includes a subresolution assist feature disposed at an angle with respect to the first feature and disposed at a second angle with respect to the second feature, wherein each of the first and second angles differ from 90 degrees. In addition, the third feature may be at a third angle with respect to an adjacent target device feature, wherein the third angle is greater than 0 degrees and less than 90 degrees.

With respect to the embodiment of the immediately preceding paragraph, each of the first and second features may comprise a subresolution assist feature. In addition, the first feature may intersect the second feature at an intersection, wherein the step of defining the third feature to connect the first feature to the second feature comprises replacing the intersection with the third feature. In one instance at the intersection, the first feature may be substantially perpendicular to the second feature. In addition, a line containing the first feature can be parallel to a line containing the second feature. In the later case, the first feature may also be non-collinear with the second feature.

Designing a reticle for a semiconductor device according to yet another embodiment of the present disclosure includes defining a target device feature of a reticle layout file and inserting a subresolution assist feature into the reticle layout file. In this embodiment, the subresolution assist feature is attached to the target device feature and has an aspect ratio of at least one. The aspect ratio is defined as a ratio of a length of the subresolution assist feature to a width of the subresolution assist feature.

In yet a further embodiment, a method of designing a reticle for a semiconductor device includes inserting a subresolution assist feature within a reticle layout file into an area encompassed by at least three target device features. In this embodiment, the subresolution assist feature is disposed outside regions defined by orthogonal projections of any edge of the at least three target devices. Furthermore, such an area does not include any target device features. In one instance, derived edges are defined from vertices of the at least three target device features, wherein the derived edges are used to determine a placement location to insert the subresolution assist feature.

FIG. 14 is a block diagram view of a system for forming a semiconductor device using the reticle having improved subresolution assist features according to one embodiment of the present disclosure. System 400 includes a light source 402 for generating radiation. This radiation may be ultra-violet light (UV), deep ultra-violet light (DUV), extreme ultra-violet light (EUV), X-rays, electron beams or ion beams. The light source 402 also guides the incident radiation onto the reticle 404. The reticle 404 contains the device layout to be imaged onto a semiconductor substrate. Reticle 404 includes a desired target design layout having improved subresolution assist features as described herein above with respect to the various embodiments. Projection optics 406 collects incident radiation that is diffracted by the reticle 404. The projection optics 406 also images the radiation pattern onto a photoresist layer 408 that resides on a semiconductor substrate 410. The resulting irradiated photoresist layer is then removed from the photolithography tool and processed with known techniques to transfer the pattern into the semiconductor substrate 410 and form circuit elements. Further processing can be carried out using known techniques to form one or more semiconductor device with the semiconductor substrate 410.

The semiconductor device substrate 410 can be a monocrystalline semiconductor wafer, a semiconductor-on-insulating wafer, or any other substrate used to form semiconductor devices. The resist layer 408 is typically coated over the wafer and is spun on to achieve a relatively planar upper surface. In addition, reticle 404 includes a transparent substrate made of quartz, glass, or the like and has design features and subresolution assist features as described herein.

The embodiments of the present disclosure can be used for a number of different types of patterning layers. For example, instead of patterning a conductive layer to make gate electrodes, the present embodiments could be used to pattern a contact level or an interconnect level of the semiconductor device. Typically, the larger benefit of the present embodiments is evidenced when forming masking levels that are considered critical. In other words, the critical masking levels are those that are designed to have features close to the resolution limit of the lithography tool. Although the embodiments of the present disclosure can be used for non-critical layers, such as some of the implant masks, the concepts of the present disclosure can be extended to the implant masks if needed. Further, the embodiments of the present disclosure can be integrated to be used with phase shifting masks. In these instances, the phase shifting material can be formed adjacent to the subresolution assist features.

In the foregoing specification, the disclosure has been described with reference to various embodiments. However, one of ordinary skill in the art appreciates that various modifications and changes can be made without departing from the scope of the present embodiments as set forth in the claims below. Accordingly, the specification and figures are to be regarded in an illustrative rather than a restrictive sense, and all such modifications are intended to be included within the scope of the present embodiments.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the term “comprises,” “comprising,” or any other variation thereof, are intended to cover a non-exclusive inclusion, such that a process, method, article, or apparatus that comprises a list of elements does not include only those elements by may include other elements not expressly listed or inherent to such process, method, article, or apparatus.

1. A method of designing a reticle for a semiconductor device, comprising:
defining a first edge of a reticle layout file, the first edge corresponding to a reference feature; and
using the reference feature to insert a subresolution assist feature into the reticle layout file, wherein the subresolution assist feature is at an angle with respect to a line containing the first edge, the angle not being 90 degrees.

2. The method of claim 1, wherein the reference feature comprises one of a target device feature or a second subresolution assist feature.

3. The method of claim 1, wherein using the reference feature comprises:
rotating the reference feature;
defining a derived edge from the rotated reference feature; and
using the derived edge to insert the subresolution assist feature.

4. The method of claim 3, wherein using the reference feature further comprises inserting the subresolution assist feature substantially parallel to a line containing the derived edge.

5. The method of claim 3, further comprising:
defining a second reference feature of the reticle layout file; and
rotating the second reference feature, wherein the derived edge is further defined from the rotated second reference feature.

6. The method of claim 5, wherein the reference feature comprises one of a first target device feature or a second subresolution assist feature, and wherein the second reference feature comprises one of a second target device feature or a third subresolution assist feature.

7. The method of claim 1, wherein the first edge comprises a first vertex and wherein using the reference feature to insert the subresolution assist feature comprises using the first vertex to insert the subresolution assist feature.

8. The method of claim 7, wherein using the reference feature further comprises:
defining a derived edge extending from the first vertex; and
using the derived edge to insert the subresolution assist feature.

9. The method of claim 8, wherein the derived edge extends from the first vertex to a second vertex of a second reference feature, wherein the reference feature comprises one of a first target device feature or a second subresolution assist feature, and wherein the second reference feature comprises one of a second target device feature or a third subresolution assist feature.

10. The method of claim 1, further comprising defining a second edge of a reticle layout file, the second edge corresponding to a second reference feature, and wherein using the reference feature to insert the subresolution assist feature comprises using the reference feature and the second reference feature to insert the subresolution assist feature.

11. The method of claim 10, wherein the subresolution assist feature is at a second angle with respect to a line containing the second edge, the second angle not being 90 degrees.

12. The method of claim 1, further comprising:
inspecting the reticle layout file to determine a location to be modified prior to defining the first edge.

13. A method of designing a reticle for a semiconductor device comprising:
defining a first feature of a reticle layout file;
defining a second feature of the reticle layout file; and
defining a third feature to connect the first feature to the second feature, wherein the third feature comprises a subresolution assist feature and is at a first angle with respect to the first feature and at a second angle with respect to the second feature, each of the first and second angles not being 90 degrees.

14. The method of claim 13 wherein each of the first and second features comprises a subresolution assist feature.

15. The method of claim 13, wherein the first feature intersects the second feature at an intersection, and wherein defining the third feature to connect the first feature to the second feature comprises replacing the intersection with the third feature.

16. The method of claim 15, wherein at the intersection, the first feature is substantially perpendicular to the second feature.

17. The method of claim 13, wherein a line containing the first feature is parallel to a line containing the second feature.

18. The method of claim 17, wherein the first feature is not collinear with the second feature.

19. The method of claim 13, wherein at least one of the first and second features comprises a target device feature.

20. The method of claim 13, wherein the third feature is at a third angle with respect to an adjacent target device feature, the third angle being greater than 0 degrees and less than 90 degrees.

21. A method of designing a reticle for a semiconductor device, comprising:
defining a target device feature of a reticle layout file; and
inserting a subresolution assist feature into the reticle layout file, wherein the subresolution assist feature is attached to the target device feature and has an aspect ratio of at least one, the aspect ratio defined as a ratio of a length of the subresolution assist feature to a width of the subresolution assist feature.

22. A method of designing a reticle for a semiconductor device, comprising:
inserting a subresolution assist feature within a reticle layout file into an area encompassed by at least three target device features, wherein the subresolution assist feature is outside regions defined by orthogonal projections of any edge of the at least three target devices and the area does not include any target device features.

23. The method of claim 22, wherein inserting the subresolution assist feature comprises:
defining derived edges from vertices of the at least three target device features; and
using the derived edges to insert the subresolution assist feature.

24. A method of forming a semiconductor device comprising:
forming a layer of resist over a substrate;
exposing the layer of resist using a reticle having a first subresolution assist feature wherein the first subresolution assist feature is placed in reference to a corresponding one of a target device feature or a second subresolution assist feature such that the first subresolution assist feature is at an angle with respect to a line containing a first edge of the corresponding one of the target device feature or a second subresolution assist feature, the angle not being 90 degrees; and
developing the layer after the step of exposing to define at least one device region of the semiconductor device.

25. The method of claim 24, wherein the first subresolution assist feature is placed in reference to the corresponding one of the target device feature or the second subresolution assist feature and in reference to a corresponding one of ad second target device feature or a third subresolution assist feature.

26. The method of claim 25, wherein the first subresolution assist feature is at a second angle with respect to a line containing a second edge of the corresponding one of the second target device feature or the third subresolution assist feature, the second angle not being 90 degrees.

27. A method of forming a semiconductor device comprising:
forming a layer of resist over a substrate;
exposing the layer of resist using a reticle having a subresolution assist feature that connects a first feature of the reticle to a second feature of the reticle, wherein the subresolution assist feature is at a first angle with respect to the first feature and at a second angle with respect to the second feature, each of the first and second angles not being 90 degrees; and
developing the layer after the step of exposing to define at least one device region of the semiconductor device.

28. The method of claim 27, wherein the first feature comprises a second subresolution assist feature and the second feature comprises a third subresolution assist feature.

29. The method of claim 27, wherein a line containing the first feature is parallel to a line containing the second feature.

30. The method of claim 29, wherein the first feature is not collinear with the second feature.

31. The method of claim 27, wherein at least one of the first and second features comprises a target device feature.

32. The method of claim 27, wherein the subresolution assist feature is at a third angle with respect to an adjacent target device feature, the third angle being greater than 0 degrees and less than 90 degrees.

33. A method of forming a semiconductor device comprising:
forming a layer of resist over a substrate;
exposing the layer of resist using a reticle having a subresolution assist feature that is attached to a target device feature of the reticle and has an aspect ratio of at least one, the aspect ratio defined as a ratio of a length of the subresolution assist feature to a width of the subresolution assist feature; and
developing the layer after the step of exposing to define at least one device region of the semiconductor device.

34. A method of forming a semiconductor device comprising:
forming a layer of resist over a substrate;
exposing the layer of resist using a reticle having a subresolution assist feature in an area of the reticle encompassed by at least three target device features, wherein the subresolution assist feature is outside regions defined by orthogonal projections of any edge of the at least three target devices and the area does not include any target device features; and,
developing the layer after the step of exposing to define at least one device of the semiconductor device.
